(19) United States
(12) Patent Application Publication
(10) Pub. No.: US 2026/0049399 A1
(43) Pub. Date: Feb. 19, 2026

(54) HYBRID SEMICONDUCTOR GAS FLOW COMPONENTS WITH SMOOTH INTERNAL WALLS

(71) Applicant: Applied Materials, Inc., Santa Clara, CA (US)

(72) Inventors: Sam Hyungsam Kim, San Jose, CA (US); Yao-Hung Yang, Santa Clara, CA (US); Sagir Kadiwala, Morgan Hill, CA (US)

(73) Assignee: Applied Materials, Inc., Santa Clara, CA (US)

(21) Appl. No.: 18/808,751

(22) Filed: Aug. 19, 2024

(51) Int. Cl. C23C 16/455; B33Y 10/00

(52) U.S. Cl. CPC C23C 16/45561; B33Y 10/00

(57) ABSTRACT

Exemplary gas flow components for a semiconductor processing system may include a 3D printed component that defines an outer body of the gas flow component. The 3D printed component may include an outer surface. The components may include a prefabricated component that is at least partially encapsulated within the 3D printed component. The prefabricated component may define a non-linear fluid flow lumen having an inlet and an outlet. The inlet and the outlet may each extend through the outer surface of the 3D printed component.

### TECHNICAL FIELD

The present technology relates to semiconductor processing chamber components and methods of manufacturing semiconductor chamber components. More specifically, the present technology relates to producing chamber components using a combination of traditional and additive manufacturing techniques.

### BACKGROUND OF THE INVENTION

Integrated circuits are made possible by processes which produce intricately patterned material layers on substrate surfaces. Producing patterned material on a substrate requires controlled methods of formation and removal of exposed material. Deposition and removal operations may include producing a local plasma in a processing region of a semiconductor processing chamber, for example, between a showerhead or gas distributor and a substrate support. Many components of the semiconductor processing chamber may define one or more lumens or channels through which gases, plasmas, and/or other flowable materials may be transported. To promote uniform flow of such materials, as well as to prevent these materials from being deposited on the sidewalls defining the lumens or channels, it is important to manufacture these sidewalls to be substantially smooth. However, as geometries of the chamber components get more complex, it may be very difficult or impossible with conventional manufacturing techniques without introducing other defects or drawbacks into the final component.

Thus, there is a need for improved systems and system components that can be used to produce high quality devices and structures. These and other needs are addressed by the present technology.

### BRIEF SUMMARY OF THE INVENTION

Exemplary gas flow components for a semiconductor processing system may include a 3D printed component that defines at least a portion of an outer body of the gas flow component. The 3D printed component may include an outer surface. The components may include a prefabricated component that is at least partially encapsulated within the 3D printed component. The prefabricated component may define a non-linear fluid flow lumen having an inlet and an outlet. The inlet and the outlet may each extend through the outer surface of the 3D printed component.

In some embodiments, the 3D printed component may define a central aperture. The outlet may extend into and may be fluidly coupled with the central aperture. A surface roughness of a wall defining the fluid flow lumen may have a surface roughness of no greater than 64 Ra. At least a portion of the outer surface of the 3D printed component may have a surface roughness of no less than 64 Ra. The gas flow component may include one of a faceplate, a mixer, and adapter, a manifold, gas box, a blocker plate, a pumping liner, or a thermal choke plate. The 3D printed component and the prefabricated component may be formed from a same material. The 3D printed component and the prefabricated component may be formed from different materials.

Some embodiments of the present technology may include gas flow component for a semiconductor processing system that may include a 3D printed component that defines at least a portion of an outer body of the gas flow component. The 3D printed component may include an outer surface. The components may include a prefabricated component that is at least partially encapsulated within the 3D printed component. The prefabricated component may define a fluid flow lumen having an inlet and an outlet. The inlet and the outlet may each extend through the outer surface of the 3D printed component. A surface roughness of a wall defining the fluid flow lumen may have a surface roughness of no greater than 64 Ra.

In some embodiments, the prefabricated component may be a first prefabricated component. The gas flow component may include a second prefabricated component that is at least partially encapsulated within the 3D printed component. One or both of the 3D printed component and the prefabricated component may include at least one of a metal, a ceramic, or a polymer. At least a portion of the fluid flow lumen may be non-linear. The 3D printed component may define one or more linear fluid channels. The prefabricated component may include an annular body. The inlet may extend from a radially outward-facing region of the annular body. The outlet may be one of a plurality of outlets. Each outlet may extend into a center of the annular body and may be fluidly coupled with a central aperture defined within the 3D printed component.

Some embodiments of the present technology may encompass methods of manufacturing a gas flow component for a semiconductor processing system. The methods may include forming a first portion of a 3D printed component using additive manufacturing. The methods may include positioning a prefabricated component against the first portion of the 3D printed component. The prefabricated component may define a fluid flow lumen having an inlet and an outlet. The methods may include forming a second portion of the 3D printed component using additive manufacturing such that the first portion and the second portion form a monolithic body that at least partially encapsulates the prefabricated component. The inlet and the outlet may extend through an outer surface of the 3D printed component.

In some embodiments, the prefabricated component may be a first prefabricated component. The methods may include positioning a second prefabricated component against the second portion of the 3D printed component. The methods may include forming a third portion of the 3D printed component using additive manufacturing such that the first portion, the second portion, and the third portion form a monolithic body that at least partially encapsulates the second prefabricated component. At least a portion of the fluid flow lumen may be non-linear. The fluid flow lumen may have a surface roughness of no greater than 64 Ra. The methods may include manufacturing the prefabricated component prior to positioning the prefabricated component against the first portion of the 3D printed component.

Such technology may provide numerous benefits over conventional systems and techniques. For example, the methods and systems may enable individual gas flow components of a semiconductor processing system to be fabricated without the need for separate sealing members (such as O-rings), while still providing fluid flow lumens with sufficiently smooth walls to promote proper fluid flow through the component. For example, the components described herein may include 3D printed portions that form a monolithic body without any seams, thus eliminating the need for internal gaskets and/or other sealing members. The components may also incorporate prefabricated (oftentimes machined, cast, and/or extruded) components that define fluid flow lumens. These prefabricated components may be formed using conventional techniques that provide smoother surface finishes than achievable using 3D printing techniques. In this way, fluid flow lumens, and particular complex, non-linear fluid flow lumens that cannot easily be reamed or otherwise smoothed, may be formed in the final component with sufficient smoothness to promote smoother and more uniform gas flows through the component. Additionally, the smoother sidewalls of these lumens may help prevent particle/residue buildup that could cause fall on particle defects on substrates being processed using such chamber components. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of a substrate processing chamber according to some embodiments of the present technology.

FIG. 2 shows a schematic isometric view of a gas flow component according to some embodiments of the present technology.

FIG. 2A shows a schematic cross-sectional top plan view of the gas flow component of FIG. 2.

FIG. 2B shows a schematic view of a portion of the gas flow component of FIG. 2 during manufacture of the gas flow component of FIG. 2.

FIG. 2C shows a schematic view of a portion of the gas flow component of FIG. 2 during manufacture of the gas flow component of FIG. 2.

FIG. 3 shows exemplary operations of a method of manufacturing a semiconductor chamber component according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. Components of the lid stack may impact flow distribution into the processing chamber. For example, the surface roughness of sidewalls defining the lumens, channels, and/or other gas flow paths of a given lid stack component or other chamber component may cause flow irregularities that may affect deposition rates and uniformity on a substrate. Additionally, this surface roughness may provide locations for residue from the precursors and/or plasmas to be deposited on the sidewalls, which may lead to particles from the deposited materials to create fall-on defects on the substrate during processing operations. The surface roughness may create small nooks that may be difficult to clean during conventional cleaning processes, as cleaning gases may not consistently reach such nooks. This may enable the deposited particles/residue to remain in the gas flow path and later fall onto the substrate.

Conventional chamber components address these issues in several ways. For example, some conventional chamber components are manufactured using linear or substantially linear gas flow paths that may be formed and/or finished using conventional machining techniques that may produce substantially smooth flow path sidewalls. However, such techniques severely limit the geometry of the resultant chamber component and flow paths, which may limit the ability of the chamber component to promote proper fluid flow and/or thermal uniformity. To overcome these limitations, some conventional chamber components may be formed with additive manufacturing techniques or by forming portions of a cross-section of a fluid pathway into two or more separate plates and later joining the plates to form the complete fluid pathway. However, additive manufacturing techniques provide insufficiently smooth surface finishes to promote uniform fluid flow and limit deposition of residue, with even the best processes providing surface finishing of no less than 64 Ra. Some conventional approaches utilize chemical etching techniques to attempt to smooth the 3D printed sidewalls, however controlling the etch rate to produce a smooth, uniform sidewall is difficult. While joining multiple plates to form fluid pathways may enable each half (or other portion) of a sidewall to be mechanically smoothed, there are joints and seams where the plates are joined that may introduce flow irregularities. Additionally, these joints need to be sealed and may introduce undesirable thermal irregularities between the joined components.

The present technology overcomes these challenges by producing hybrid gas flow components that may include a 3D printed (or otherwise produced using additive manufacturing techniques) component and a machined/prefabricated (or otherwise formed using traditional non-additive manufacturing techniques) component. The prefabricated component may be formed prior to the additive manufacturing process and may be produced using manufacturing techniques (such as machining, casting, forging, etc.) that may produce a surface roughness of less than 64 Ra. One or more lumens, channels, and/or other gas fluid paths may be defined within the prefabricated component, ensuring that the gas fluid paths have sufficiently smooth sidewalls to promote uniform flow through the gas flow component. The prefabricated component may be at least partially encapsulated within the 3D printed component. This may enable the 3D printing or other additive manufacturing process to be used to produce the main body of the component while ensuring that the smaller and/or more complex fluid flow paths are sufficiently smooth, while the use of 3D printing may enable the fabrication of chamber components having more complex geometries than those produced by traditional machining processes, may help eliminate seams formed when joining multiple pieces of material to form a part with the internal volumes, and may eliminate and/or reduce the need for some finishing steps, such as grinding, which may help increase the fabrication time of the components. Accordingly, the present technology may produce improved film deposition characterized by improved thickness and material property uniformity across a surface of the substrate.

Although the remaining disclosure will routinely identify specific deposition chambers utilizing the disclosed technology, it will be readily understood that the systems and methods are equally applicable to other deposition and cleaning chambers, as well as processes as may occur in the described chambers. Accordingly, the technology should not be considered to be so limited as for use with these specific chambers alone. The disclosure will discuss one possible system and chamber that may include lid stack components according to embodiments of the present technology before additional variations and adjustments to this system according to embodiments of the present technology are described.

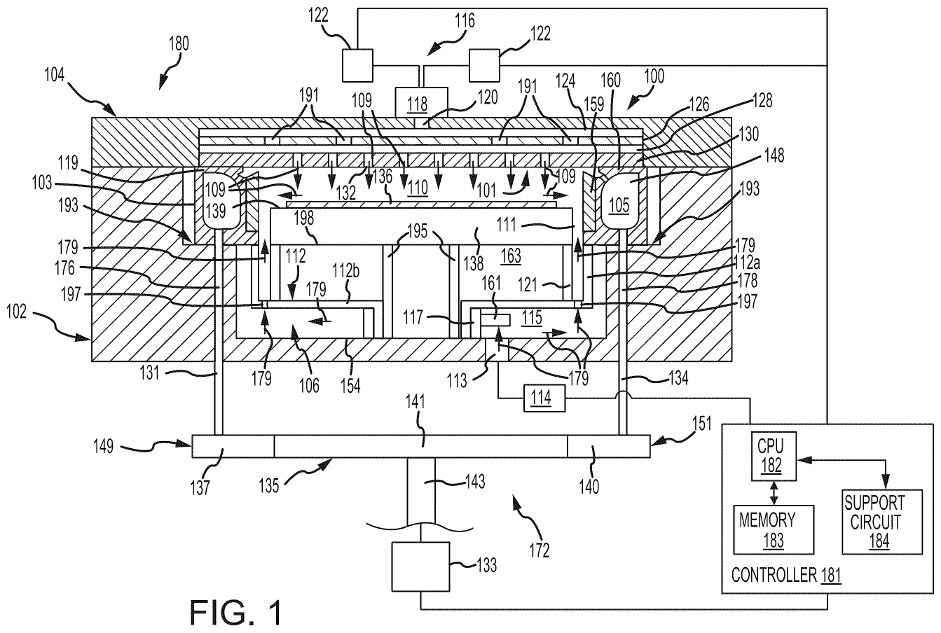

FIG. 1 shows a schematic cross-sectional view of an exemplary substrate processing chamber 100, according to one implementation. The substrate processing chamber 100 may be, for example, a chemical vapor deposition (CVD) chamber or a plasma enhanced CVD chamber. The present disclosure contemplates that other chambers may be used, such as an atomic layer deposition (ALD) chamber or a physical vapor deposition (PVD) chamber. The substrate processing chamber 100 may have a chamber body 102 and a chamber lid 104 disposed on the chamber body 102. The chamber body 102 may define an internal volume 106 between one or more sidewalls and a base of the chamber body 102 and the chamber lid 104. The chamber body 102 may be made of a single body, or two or more bodies.

The substrate processing chamber 100 may include a gas distribution assembly 116 coupled to or disposed in the chamber lid 104 to deliver a flow of one or more process gases 109 into a processing region 110 through a showerhead 101, which may form a portion of the gas distribution assembly 116. The one or more process gases may include one or more of Ar and/or C3H6, among other gases. In one example, the one or more process gases may include one or more reactive gases. The showerhead 101 may include a backing plate 126 and a faceplate 130. The gas distribution assembly 116 may include a gas mixer or gas manifold 118 coupled to a gas inlet passage 120 formed in the chamber lid 104. The gas manifold 118 may receive a flow of one or more processing gases from one or more gas sources 122. While two gas sources 122 are shown, any number of gas sources may be provided in various embodiments. In some embodiments, one or more of the gas sources 122 may be a gas panel and/or a remote plasma unit. For example, flow from a remote plasma unit may be introduced into one inlet of the gas manifold 118 while gases from one or more gas panels may be introduced into a different inlet of the gas manifold 118. Flows from each gas source 122 may be maintained in isolation through the gas manifold 118 and/or may be mixed in one or more channels or lumens of the gas manifold 118. The flow of processing gases received from the one or more gas sources 122 may distribute across a gas box 124, flow through a plurality of openings 191 of the backing plate 126, and further distribute across a plenum 128 defined by the backing plate 126 and the faceplate 130. The flow of processing gases 109 may then flow into a processing region 110 of the internal volume 106 through one or more gas openings 132 formed in a lower surface 119 of the faceplate 130 of the showerhead 101.

A substrate support 138 may be disposed within internal volume 106 defined by the chamber body 102. The substrate supports 138 may be pedestals as illustrated, although a number of other configurations may also be used. The substrate support 138 may support a substrate 136 within the substrate processing chamber 100. The substrate support 138 may support the substrate 136 on a support surface 139 of the substrate support 138. The substrate support 138 may include a heater and/or an electrode disposed therein. The electrode may receive direct current (DC) voltage, radio frequency (RF) energy, and/or alternating current (AC) energy to facilitate processing. The lower surface 119 of the faceplate 130 of the showerhead 101 may face the support surface 139 of the substrate support 138. The support surface 139 may face the lower surface 119 of the faceplate 130 of the showerhead 101. The substrate support 138 may be made of a single body, or two or more bodies.

The substrate support 138 may be movably disposed in the internal volume 106 by a lift system 195. Movement of the substrate support 138 may facilitate transfer of the substrate 136 to and from the internal volume 106 through a slit valve formed through the chamber body 102. The substrate support 138 may also be moved to different processing positions for processing of the substrate 136.

During substrate processing, as process gases (such as the process gases 109) flow into the processing region 110, a heater may heat the substrate support 138 and the support surface 139. Also during substrate processing, the electrode in the substrate support 138 may propagate radio frequency (RF) energy, alternating current (AC), or direct current (DC) voltage to facilitate plasma generation in the processing region 110 and/or to facilitate chucking of the substrate 136 to the substrate support 138. The heat, gases, and energy from the electrode in the substrate support 138 may facilitate deposition of a film onto the substrate 136 during substrate processing. The faceplate 130, which may be grounded via coupling to the chamber body 102, and the electrode of the substrate support 138, may facilitate formation of a capacitive plasma coupling. When power is supplied to the electrode in the substrate support 138, an electric field may be generated between the faceplate 130 and substrate support 138 such that atoms of gases present in the processing region 110 between the substrate support 138 and the faceplate 130 are ionized and release electrons. The ionized atoms accelerate to the substrate support 138 to facilitate film formation on the substrate 136.

A pumping device 103 may be disposed in the substrate processing chamber 100. The pumping device 103 may facilitate removal of gases from the internal volume 106 and processing region 110. The gases exhausted by the pumping device 103 may include one or more of a process gas and a process residue. The process residue may result from the process of depositing a film onto the substrate 136.

The pumping device 103 may include a pumping liner 160 disposed on the chamber body 102. For example, the pumping liner 160 may be seated on a stepped surface 193 of the chamber body 102 and a liner 159 may be disposed between the substrate support 138 and the pumping liner 160. The stepped surface 193 may be stepped upwards from a bottom surface 154 of the chamber body 102. The pumping liner 160 may be made of a single body, or two or more bodies. The pumping liner 160 may be made from material including one or more of aluminum, aluminum oxide, and/or aluminum nitride. The liner 159 may be made from an electrically isolating material, such as a ceramic material. In one example, the liner 159 may be made of one or more of quartz, a ceramic material including aluminum such as aluminum oxide and/or aluminum nitride, or any other suitable material. The pumping liner 160 may be disposed around the substrate support 138 and may encircle the substrate support 138. A portion of a purge gas flow path 111 may be defined by an inner surface of the liner 159 and a lateral exterior surface of the substrate support 138. The substrate processing chamber 100 may include a purge gas inlet 113 disposed at a bottom of the chamber body 102. The purge gas inlet 113 may be an opening formed in a bottom surface of the chamber body 102. The purge gas inlet 113 may be fluidly coupled with a purge gas source 114 that supplies one or more purge gases 179 to the purge gas inlet 113. A bowl 112 may be disposed in the internal volume 106. The bowl 112 may define a purge gas volume 115. One or more bellows 117 may be disposed in the purge gas volume 115. One or more purge gas baffles 161 may be disposed in the purge gas volume 115. One or more bellows 121 may be disposed above a horizontal portion 112b of the bowl 112 and below a bottom surface 198 of the substrate support 138. The one or more bellows 121 may separate a dead volume 163 from a portion of the purge gas flow path 111 that is between the one or more bellows 121 and a vertical portion 112a of the bowl 112.

During substrate processing operations, and while processing gases 109 flow into the processing region 110 from the showerhead 101, the purge gas inlet 113 may flow the one or more purge gases 179 into the purge gas volume 115. The horizontal portion 112b of the bowl 112 may include one or more purge gas openings 197 that flow the purge gases 179 from the purge gas volume 115 and into the purge gas flow path 111. The one or more purge gas openings 197 may be disposed radially outwardly of the one or more bellows 121. While the processing gases 109 flow toward the substrate 136 to deposit films on the substrate 136, the purge gases 179 may flow upwards in the purge gas flow path 111 to prevent the processing gases 109 from diffusing downwards into the purge gas flow path 111. The processing gases 109 and the purge gases 179 may meet and/or mix at a diffusion position that is proximate the support surface 139. The processing gases 109 and the purge gases 179 may mix to form a gas mixture 148 that is exhausted by the pumping device 103. The pumping device 103 may include the pumping liner 160 and the liner 159.

The one or more purge gases 179 may include one or more inert gases, such as one or more of Ar and/or N2. The one or more process gases 109 may flow into the processing region 110 from the showerhead 101 at a first flow rate. In one example, the first flow rate may be a volumetric flow rate having units of standard cubic centimeters per minute (SCCM). The one or more purge gases 179 may flow into the purge gas volume 115 from the purge gas inlet 113 at a second flow rate. In one example, the second flow rate may be a volumetric flow rate having units of SCCM. The second flow rate may be a ratio R1 relative to the first flow rate. For example, the ratio R1 may be within a range of 0.25 to 0.75 of the first flow rate, within a range of 0.25 to 0.50 of the first flow rate, or within a range of 0.48 to 0.52. In one embodiment, which can be combined with other embodiments, the ratio R1 may be about 0.25, 0.30, 0.40, or 0.5 of the first flow rate. The ranges and examples of the ratio R1 of the second flow rate relative to the first flow rate may incur benefits such as preventing at least a portion of processing gases from diffusing into the purge gas flow path 111 below the support surface 139 during substrate processing operations. Reducing or preventing such diffusion reduces or eliminates the likelihood that processing gases 109 will deposit materials onto surfaces other than the substrate 136. Reducing deposition on surfaces other than the substrate 136 reduces or eliminates delays, throughput reductions, operational costs, cleaning time, and/or substrate defects.

The substrate processing chamber 100 may be part of a substrate processing system 180 that includes a controller 181 coupled to the substrate processing chamber 100. The controller 181 may be part of a non-transitory computer readable medium.

The controller 181 may control aspects of the substrate processing chamber 100 during substrate processing. The controller 181 include a central processing unit (CPU) 182, a memory 183, and a support circuit 184 for the CPU 182. The controller 181 may facilitate control of the components of the substrate processing chamber 100. The controller 181 may be a computer that can be used in an industrial setting for controlling various chamber components and sub-processors. The memory 183 may store instructions, such as software (source code or object code), that may be executed or invoked to control the overall operations of the substrate processing chamber 100 in manners described herein. The controller 181 may manipulate respective operations of controllable components in the substrate processing chamber 100. For example, the controller 181 may control the operations of the gas sources 122 to introduce processing gases, the purge gas source 114 to introduce purge gases, and/or a vacuum pump 133 (described below) to exhaust gases to eliminate or reduce contaminant particles (such as residue) in the substrate processing chamber. As an example, the controller 181 may control the lift system 195 to raise and lower the substrate support 138, and the heater and the electrode of the substrate support 138 to supply heat and energy to facilitate processing.

The pumping liner 160 may be fluidly coupled to a foreline 172 through a first conduit 176 and a second conduit 178. The foreline 172 may include a first vertical conduit 131, a second vertical conduit 134, a horizontal conduit 135, and an exit conduit 143. The exit conduit 143, in one example, is a third vertical conduit. In one example, the first conduit 176 and the second conduit 178 may be openings formed in the chamber body 102. The first conduit 176 and/or the second conduit 178 may be tubes or other flow devices that extend between a surface of the chamber body 102, such as bottom surface 154, and the pumping liner 160. As an example, the first conduit 176 and/or the second conduit 178 may be part of the first vertical conduit 131 and the second vertical conduit 134, respectively. In such an example, the first vertical conduit 131 and the second vertical conduit 134 may extend through the chamber body 102 and be coupled to the pumping liner 160. In one embodiment, which can be combined with other embodiments, the first conduit 176 and the second conduit 178 each may be an opening formed in one or more sidewalls of the chamber body 102.

The first conduit 176 may be fluidly coupled to the pumping liner 160 and the first vertical conduit 131 of the foreline 172. The second conduit 178 may be fluidly coupled to the pumping liner 160 and the second vertical conduit 134 of the foreline 172. The first vertical conduit 131 and the second vertical conduit 134 may be fluidly coupled to the horizontal conduit 135. The horizontal conduit 135 may include a first portion 137 coupled to the first vertical conduit 131, a second portion 140 coupled to the second vertical conduit 134, and a third portion 141 coupled to the exit conduit 143. The horizontal conduit 135 may include a first end 149 adjacent to the first vertical conduit 131 and a second end 151 adjacent to the second vertical conduit 134. The horizontal conduit 135 may be made up of a single body or can be fabricated from one or more components.

The first conduit 176, second conduit 178, first vertical conduit 131, second vertical conduit 134, and horizontal conduit 135 may be configured to direct gases therethrough. The first conduit 176, second conduit 178, first vertical conduit 131 and/or second vertical conduit 134 need not be completely vertical and may be angled or may include one or more bends and/or angles. The present horizontal conduit 135 need not be completely horizontal and may be angled or may include one or more bends and/or angles.

The exit conduit 143 may be fluidly coupled to a vacuum pump 133 to control the pressure within the processing region 110 and to exhaust gases and residue from the processing region 110. The vacuum pump 133 may exhaust gases from the processing region 110 through the pumping liner 160, the first conduit 176, the second conduit 178, the first vertical conduit 131, the second vertical conduit 134, the horizontal conduit 135, and the exit conduit 143 of the foreline 172.

The pumping liner 160 may be fluidly coupled to the exit conduit 143 through the second conduit 178, second vertical conduit 134 and the horizontal conduit 135. The gas mixture 148 may flow from the annulus 105, through the exhaust port 145, and into the second conduit 178. A second exhaust port of the pumping liner 160 may be disposed between the annulus 105 and the first conduit 176. The second exhaust port may be fluidly coupled to the exit conduit 143 through the first conduit 176, first vertical conduit 131 and the horizontal conduit 135. In addition to flowing through the exhaust port 145, the gas mixture 148 may flow through the second exhaust port and into the first conduit 176.

The first vertical conduit 131 may flow the gas mixture 148 from the first conduit 176 and into the first portion 137 of the horizontal conduit 135. The second vertical conduit 134 may flow the gas mixture 148 from the second conduit 178 and into the second portion 140 of the horizontal conduit 135. The first portion 137 and the second portion of the horizontal conduit 135 may flow the gas mixture 148 from the first vertical conduit 131 and the second vertical conduit 134, respectively, and into the third portion 141 of the horizontal conduit 135. The third portion 141 of the horizontal conduit 135 may flow the gas mixture 148 from the horizontal conduit 135 and into the exit conduit 143. The exit conduit 143 may exhaust the gas mixture 148 from the exhaust port 145 and the second exhaust port that is disposed between the annulus 105 and the first conduit 176.

Although two conduits 176, 178; two vertical conduits 131, 134; and a pumping liner 160 with an exhaust port 145 and a second exhaust port are illustrated, any number of conduits, vertical conduits, and/or exhaust ports may be implemented in various embodiments. For example, the pumping liner 160 may have at least three exhaust ports that are fluidly coupled to respective conduits and vertical conduits. The third conduit may be coupled to the third vertical conduit and the third vertical conduit may be coupled to the horizontal conduit 135. The three exhaust ports may be disposed along a circumferential axis of the pumping liner 160 approximately equidistant from each other, such as 120 degrees from each other.

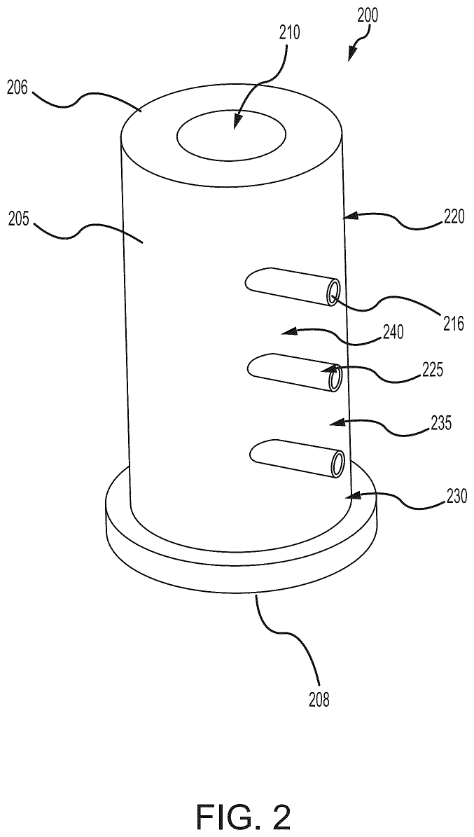

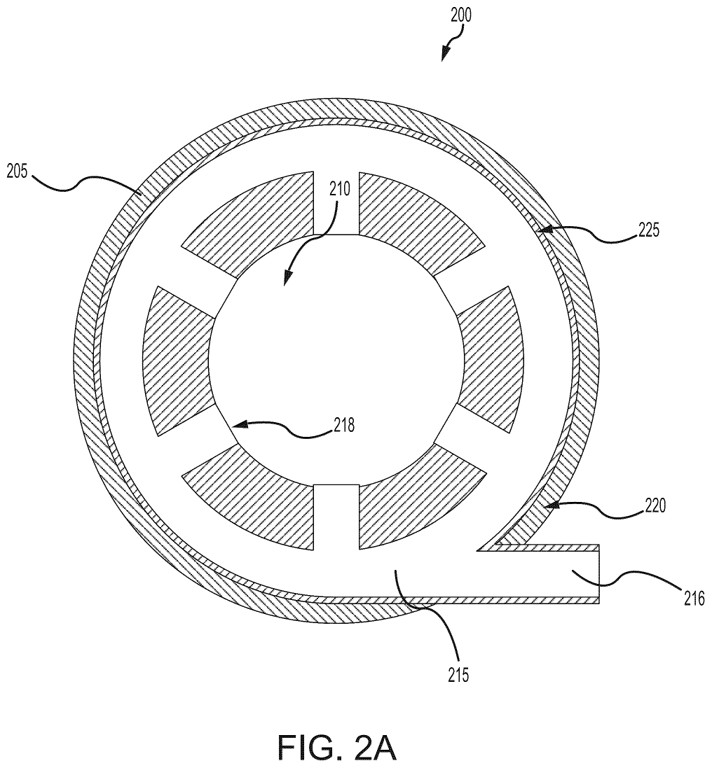

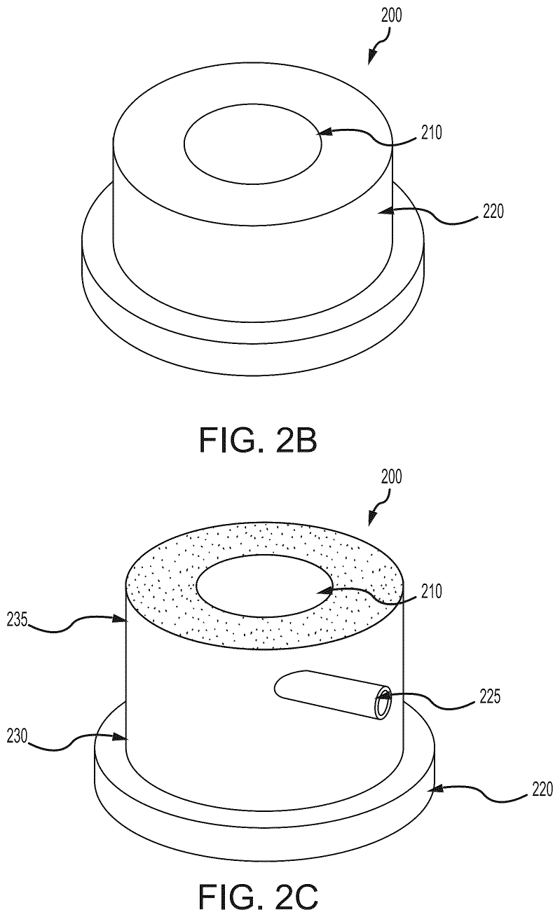

FIGS. 2A and 2B show an exemplary gas flow component 200 of a semiconductor processing system. Gas flow component 200 may be any component through which one or more gases, other fluids, and/or plasmas is flowed before or after introduction to one or more processing chambers. In some embodiments, the gas flow component 200 may be a lid stack component and may form at least a portion of a gas distribution assembly, such as gas distribution assembly 116 described above. For example, the gas flow component 200 may be, without limitation, a showerhead, a faceplate, a blocker plate, a gasbox, a gas mixer, a gas manifold, an adapter, and/or other chamber component. As illustrated, the gas flow component 200 is in the form of a gas mixer that may receive one or more gases and/or plasmas from one or more gas or plasma sources (such as a remote plasma unit and/or gas panel), such as gas sources 122 described above. Each gas and/or plasma flow may be introduced into a separate inlet and may be later mixed for delivery to other downstream components of a processing chamber.

For example, gas flow component 200 may include a body 205 that may include a first end 206 and a second end 208 opposite the first end 206. In some embodiments, the first end 206 forms an inlet or upstream end of the gas flow component 200, while the second end 208 forms an outlet or downstream end of the gas flow component 200. In the illustrated embodiment, the body 205 defines or otherwise includes a central aperture 210 that extends from the first end 206 to the second end 208 such that an inlet of the central aperture 210 extends through the first end 206 and an outlet of the central aperture 210 extends through the second end 208. In some embodiments, the central aperture 210 may have a constant diameter (or other lateral dimension) and/or cross-sectional shape, while in other embodiments, a diameter (or other lateral dimension) and/or cross-sectional shape of the central aperture 210 may vary along a length of the body 205.

The gas flow component 200 may include or define one or more fluid flow lumens 215, which may each include an inlet 216 and one or more outlets 218. It will be appreciated that the gas flow component 200 may include any number of fluid flow lumens 215. For example, As illustrated, the inlets 216 are aligned in a linear manner and extend through a radially outward-facing portion of the outer surface of the body 205, although other configurations are possible. For example, one or more of the inlets 216 may be arranged at different angular positions relative to a longitudinal axis of the body 205. In some embodiments, the inlets 216 may be flush with an outer surface of the body 205, while in other embodiments the inlets may extend outward beyond the outer surface of the body 205. As best illustrated in FIG. 2B, at least some of the fluid flow lumens 215 may include linear and/or arcuate segments, although any shape of fluid flow lumens 215 may be included in various embodiments. Some or all of the outlets 218 may extend into and be fluidly coupled with the central aperture 210. For example, one or more of the outlets 218 may extend through a sidewall of the body 205 that defines the central aperture 210. Such outlets 218 may be radially arranged (e.g., have longitudinal axes that intersect a longitudinal axis of the central aperture 210 and/or the body 205) as shown here, or may be angled relative to a longitudinal axis of the central aperture 210 and/or the body 205 (e.g., do not intersect the longitudinal axis). While shown with each fluid flow lumen 215 having six outlets 218, it will be appreciated that each fluid flow lumen 215 may have any number of outlets 218. For example, each fluid flow lumen 215 may include one or more outlets, two or more outlets, three or more outlets, four or more outlets, five or more outlets, six or more outlets, eight or more outlets, ten or more outlets, fifteen or more outlets, twenty or more outlets, or more. It will be appreciated that in some embodiments, each fluid flow lumen 215 may include a same structure (e.g., size, shape, number of outlets, etc.), while in other embodiments, one or more of the fluid flow lumens 215 may have a different structure than at least one other fluid flow lumen 215.

In some embodiments, at least a portion of the body 205 may be formed from a 3D printed component 220 (or component formed from other additive manufacturing techniques). For example, the 3D printed component 220 may define all or a portion of an outer surface of the body 205. The 3D printed component 220 may define one or more linear or otherwise simple fluid flow lumens. For example, the 3D printed component 220 may define the central aperture 210 in some embodiments. Given the linear and/or tapered shaped of the central aperture 210, conventional machining and/or finishing techniques (such as reaming, burnishing, chemical etching and/or milling, etc.) may be used to create a desired surface roughness within the central aperture 210. For example, in some embodiments, a surface roughness of the central aperture 210 may be no greater than 64 Ra, no greater than 60 Ra, no greater than 55 Ra, no greater than 50 Ra, no greater than 45 Ra, no greater than 40 Ra, no greater than 35 Ra, no greater than 30 Ra, no greater than 25 Ra, no greater than 20 Ra, no greater than 15 Ra, or less. In some embodiments, some or all of the remaining portion of the outer surface of the 3D printed component 220 and/or the body 205 may have a surface roughness of at least 64 Ra, at least 70 Ra, at least 80 Ra, at least 90 Ra, at least 100 Ra, at least 125 Ra, at least 150 Ra, 175 Ra, at least 200 Ra, or greater. In some embodiments, some or all of the outer surface of the 3D printed component 220 and/or the body 205 may be smoothed, such as via filing, grinding, sanding, and the like. In such embodiments, such portions of the outer surface may have a surface roughness of no greater than 64 Ra.

In some embodiments, the gas flow component 200 may include at least one prefabricated component 225 that may be at least partially encapsulated within the 3D printed component 220 to form a monolithic body. In some embodiments, each prefabricated component 225 may define at least a portion of one of the fluid flow lumens 215. For example, in the illustrated embodiment, each fluid flow lumen 215 is defined by a separate prefabricated component 225. Each prefabricated component 225 may be formed using traditional manufacturing techniques such as, but not limited to, machining, casting, extruding, forging, and/or other processing. The formation of the prefabricated component 225 using traditional techniques may enable the fluid flow lumen(s) 215 defined by each prefabricated component 225 to be defined by sidewalls having a sufficiently smooth surface roughness (e.g., a surface roughness of no greater than 64 Ra), while still enabling one or more of the fluid flow lumens 215 to have a complex (e.g., non-linear) shape that would otherwise be difficult to smooth in a uniform manner using post processing techniques. For example, in one particular embodiment, each prefabricated component 225 may include a single fluid flow lumen 215, which may include an inlet 216 and a number of outlets 218 that extend through an outer surface of the 3D printed component 220. The prefabricated component 225 may be formed prior to formation of the 3D printed component 220. For example, the prefabricated component 225 may be machined, extruded, or otherwise formed as a linear component with a linear, smooth borehole that becomes a portion of the fluid flow lumen 215. The original linear nature of the borehole may enable the borehole to be formed or finished with substantially smooth (e.g., having a surface roughness of no greater than 64 Ra) walls. The component may be bent and subsequently welded or otherwise secured to form a generally annular body having the inlet 216 and the outlets 218 and a generally annular fluid flow lumen 215.

In some embodiments, the 3D printed component 220 and the prefabricated component 225 may formed from the same material, while in other embodiments, the 3D printed component 220 and the prefabricated component 225 may be formed from different materials. The 3D printed component 220 and the prefabricated component 225 may be formed from various materials such as, but not limited to, metals, dielectric materials, ceramics, polymeric materials, and the like. Additionally, while shown here as a gas mixer, the gas flow component 200 may take the form of other chamber components in various embodiments. For example, the gas flow component 200 may be a faceplate, a mixer, and adapter, a manifold, gas box, a blocker plate, a pumping liner, a thermal choke plate, and/or component of a semiconductor processing system. It will be appreciated that the design of the gas flow component 200 is merely provided as one example and that numerous variations may exist. For example, the gas flow component 200 may include more or fewer prefabricated components 225, with some or all of the prefabricated components 225 having different structures than that illustrated. Additionally, the 3D printed component 220 and/or the body 205 may include more or fewer apertures/gas channels in various embodiments.

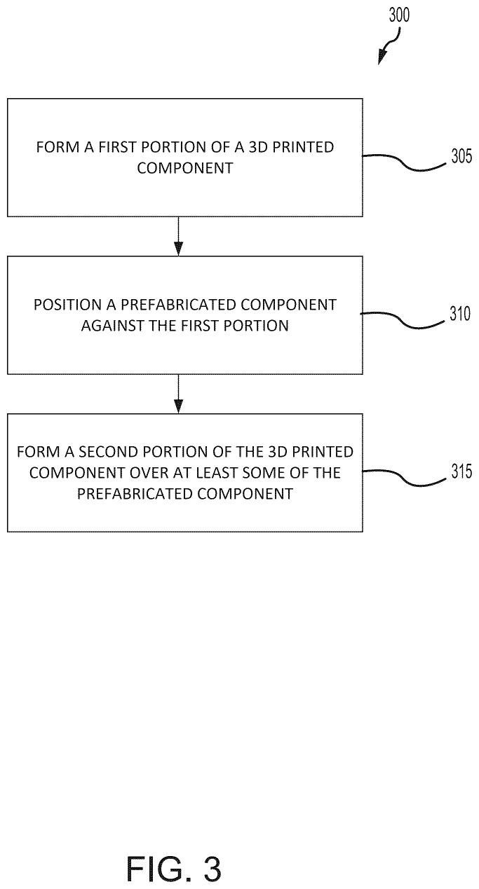

FIG. 3 shows exemplary operations in a method 300 for manufacturing a gas flow component for a semiconductor processing system according to some embodiments of the present technology. The method may be performed to produce a variety of processing chamber components, including gas flow component 200 described above. Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 300 describes operations shown schematically in FIGS. 2B and 2C, the illustrations of which will be described in conjunction with the operations of method 300. It is to be understood that FIGS. 2B and 2C illustrate only partial schematic views, and a gas flow component 200 may include various features as illustrated in the figures, as well as alternative features, of any size or configuration that may still benefit from aspects of the present technology. In some embodiments, method 300 may include forming a first portion 230 of the 3D printed component 220 using additive manufacturing at operation 305 as shown in FIG. 2B. For example, one or more layers of material may be formed using 3D printing or other additive manufacturing techniques to form the portion of the 3D printed component. Various forms of 3D printing techniques may be utilized such as, but not limited to, selective laser sintering, fused deposition modeling, multi-jet fusion printing, direct metal laser sintering, electron beam melting, digital light process, binder jetting, powder bed fusion, and/or other additive manufacturing techniques.

Once the first portion 230 of the 3D printed component 220 has been formed, a prefabricated component, such as prefabricated component 225, may be positioned atop or otherwise against the first portion 230 of the 3D printed component 220 at operation 310. As noted above, the prefabricated component 225 may define a fluid flow lumen 215 having an inlet 216 and one or more outlets (as shown in FIG. 2A). The inlet 216 and each outlet may protrude through the exterior surface of the 3D printed component 220. At operation 315, a second portion 235 of the 3D printed component 220 may be formed using additive manufacturing as shown in FIG. 2C. For example, one or more layers of material may be applied to the first portion 230 and the prefabricated component 225 such that the first portion 230 and the second portion 235 form a monolithic body that at least partially encapsulates the prefabricated component 225. Such a design enables the prefabricated component 225 to define the fluid flow lumen 215, while providing interior lumen walls have a surface roughness of no greater than 64 Ra.

In some embodiments, such as illustrated in FIG. 2, the gas flow component 200 may include multiple prefabricated components 225. In such embodiments, the method 300 may include additional printing steps. For example, after forming the second portion 235 of the 3D printed component 220, a second prefabricated component 225 may be positioned atop or otherwise against the second portion 235. The second prefabricated component 225 may have a same or different structure than the first prefabricated component 225. A third portion 240 of the 3D printed component 220 may be formed using additive manufacturing. For example, one or more layers of material may be applied to the second portion 235 and the second prefabricated component 225 such that the first portion 230, the second portion 235, and the third portion 240 form a monolithic body that at least partially encapsulates both prefabricated components 225. Such processes may be repeated any number of times to at least partially encapsulate any number of prefabricated components 225 into the final 3D printed component 220.

In some embodiments, once the 3D printed component 220 (and thus the body 205 of the gas flow component 200) has been fully formed, one or more additional processing operations may be performed. For example, the 3D printed component 220 and/or the body 205 of the gas flow component 200 may be sintered, annealed, machined, coated, and/or otherwise processed to finish the gas flow component 200, thereby providing a working component that can be incorporated in a semiconductor processing system. An advantage of using a sintered material may include that a finished component may serve as a refractory conductor, with favorable thermal deformation characteristics and chemical resistance to plasma etching, as well as electrical conductivity.

The use of 3D printing (or other additive manufacturing techniques) may provide further benefits over using conventional machining and other fabrication techniques. For example, the use of 3D printing may enable the fabrication of chamber components having more complex geometries than those produced by traditional machining processes. Internal channels, voids, and/or other areas may be formed without the need for tool access, which may help eliminate seams formed when joining multiple pieces of material to form a part with the internal volumes. Additionally, 3D printing techniques may eliminate and/or reduce the need for some finishing steps, such as grinding, which may help increase the fabrication time of the components. Moreover, by integrating prefabricated components that define more complex fluid lumens, embodiments may enable such complex fluid lumens to be fabricated with smoother surface finishes than are achievable using additive manufacturing techniques and that would otherwise be difficult to achieve post-printing due to the complexity of the internal lumens/features.

In some embodiments, the method 300 may also include manufacturing each prefabricated component 225 prior to positioning the respective prefabricated component 225 against a respective portion of the 3D printed component 220. For example, the prefabricated component 225 may be machined, separately 3D printed, extruded, cast, forged and/or otherwise formed prior to being positioned against a portion of the 3D printed body. In some embodiments, the fluid flow lumens may be polished and/or otherwise smoothed to a surface roughness of no greater than 64 Ra prior to bending the body of the prefabricated component 225 and/or otherwise forming a non-linear fluid flow lumen 215. This may ensure that the walls defining the fluid flow lumen 215 are sufficiently smooth prior to the formation of the gas flow component 200.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a cutout” includes a plurality of such cutouts, and reference to “the flange” includes reference to one or more flanges and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A gas flow component for a semiconductor processing system, comprising:
a 3D printed component that defines at least a portion of an outer body of the gas flow component, the 3D printed component comprising an outer surface; and
a prefabricated component that is at least partially encapsulated within the 3D printed component, the prefabricated component defining a non-linear fluid flow lumen having an inlet and an outlet, wherein the inlet and the outlet each extend through the outer surface of the 3D printed component.

2. The gas flow component for a semiconductor processing system of claim 1, wherein:
the 3D printed component defines a central aperture.

3. The gas flow component for a semiconductor processing system of claim 2, wherein:
the outlet extends into and is fluidly coupled with the central aperture.

4. The gas flow component for a semiconductor processing system of claim 1, wherein:
a surface roughness of a wall defining the fluid flow lumen has a surface roughness of no greater than 64 Ra.

5. The gas flow component for a semiconductor processing system of claim 1, wherein:
at least a portion of the outer surface of the 3D printed component has a surface roughness of no less than 64 Ra.

6. The gas flow component for a semiconductor processing system of claim 1, wherein:
the gas flow component comprises one of a faceplate, a mixer, and adapter, a manifold, gas box, a blocker plate, a pumping liner, or a thermal choke plate.

7. The gas flow component for a semiconductor processing system of claim 1, wherein:
the 3D printed component and the prefabricated component are formed from a same material.

8. The gas flow component for a semiconductor processing system of claim 1, wherein:
the 3D printed component and the prefabricated component are formed from different materials.

9. A gas flow component for a semiconductor processing system, comprising:
a 3D printed component that defines at least a portion of an outer body of the gas flow component, the 3D printed component comprising an outer surface; and
a prefabricated component that is at least partially encapsulated within the 3D printed component, the prefabricated component defining a fluid flow lumen having an inlet and an outlet, wherein:
the inlet and the outlet each extend through the outer surface of the 3D printed component; and
a surface roughness of a wall defining the fluid flow lumen has a surface roughness of no greater than 64 Ra.

10. The gas flow component for a semiconductor processing system of claim 9, wherein:
the prefabricated component is a first prefabricated component; and
the gas flow component further comprises a second prefabricated component that is at least partially encapsulated within the 3D printed component.

11. The gas flow component for a semiconductor processing system of claim 9, wherein:
one or both of the 3D printed component and the prefabricated component comprises at least one of a metal, a ceramic, or a polymer.

12. The gas flow component for a semiconductor processing system of claim 9, wherein:
at least a portion of the fluid flow lumen is non-linear.

13. The gas flow component for a semiconductor processing system of claim 9, wherein:
the 3D printed component defines one or more linear fluid channels.

14. The gas flow component for a semiconductor processing system of claim 9, wherein:
the prefabricated component comprises an annular body.

15. The gas flow component for a semiconductor processing system of claim 14, wherein:
the inlet extends from a radially outward-facing region of the annular body;
the outlet is one of a plurality of outlets; and
each outlet extends into a center of the annular body and is fluidly coupled with a central aperture defined within the 3D printed component.

16. A method of manufacturing a gas flow component for a semiconductor processing system, comprising:
forming a first portion of a 3D printed component using additive manufacturing;
positioning a prefabricated component against the first portion of the 3D printed component, the prefabricated component defining a fluid flow lumen having an inlet and an outlet; and
forming a second portion of the 3D printed component using additive manufacturing such that the first portion and the second portion form a monolithic body that at least partially encapsulates the prefabricated component, wherein the inlet and the outlet extend through an outer surface of the 3D printed component.

17. The method of manufacturing a gas flow component for a semiconductor processing system of claim 16, wherein:
the prefabricated component is a first prefabricated component;
the method further comprises:
positioning a second prefabricated component against the second portion of the 3D printed component; and
forming a third portion of the 3D printed component using additive manufacturing such that the first portion, the second portion, and the third portion form a monolithic body that at least partially encapsulates the second prefabricated component.

18. The method of manufacturing a gas flow component for a semiconductor processing system of claim 16, wherein:
at least a portion of the fluid flow lumen is non-linear.

19. The method of manufacturing a gas flow component for a semiconductor processing system of claim 16, wherein:
the fluid flow lumen has a surface roughness of no greater than 64 Ra.

20. The method of manufacturing a gas flow component for a semiconductor processing system of claim 16, further comprising:
manufacturing the prefabricated component prior to positioning the prefabricated component against the first portion of the 3D printed component.
